(19) United States
(12) Patent Application Publication
(10) Pub. No.: US 2011/0214722 A1
(43) Pub. Date: Sep. 8, 2011

(54) THIN FILM SOLAR CELL

(76) Inventors: Chien-Chung BI, Houli Township (TW); Kuang-Chieh Lai, Houli Township (TW)

(21) Appl. No.: 12/718,155

(22) Filed: Mar. 5, 2010

(51) Int. Cl. H01L 31/00

(52) U.S. Cl. 136/255; 136/261; 136/252

(57) ABSTRACT

The present invention relates to a thin film solar cell. The thin film solar cell comprises a substrate, a transparent conductive layer, a first semiconductor layer, a reflection layer, a reflection enhancing layer, a second semiconductor layer and an electrode layer. The transparent conductive layer is formed on the substrate. The first semiconductor layer is formed on the transparent conductive layer. The reflection layer is formed on the first semiconductor layer, and it is highly refraction and has a plurality of light-transmissive parts. The reflection enhancing layer is formed on the reflection layer, and it has at least a stacking layer including a low refraction index layer and a high refraction index layer. The second semiconductor layer is formed on the reflection enhancing layer. The electrode layer is formed on the second semiconductor layer. The light-transmissive parts are extended to the reflection enhancing layer.

### FIELD OF THE INVENTION

The present invention relates to a solar cell, and more particularly to a thin film solar cell having enhanced photoelectric conversion efficiency by increasing photo-absorption rate in a semiconductor layer of the thin film solar cell.

### DESCRIPTION OF PRIOR ART

Solar cells are a photoelectric conversion device by means of utilizing photovoltaic effect to enable conversion of photon energy so as to generate an electronic voltage. Solar cells have become an attractive alternative energy due to its inexhaustibility, purity, and safety. Solar cells can be distinguished by material, manufacture, and structure into monocrystalline silicon solar cells, polycrystalline silicon solar cells, amorphous silicon solar cells, and thin film solar cell etc. In the aforementioned different kinds of solar cells, the development of thin film solar cell not only reduces cost but also improves photoelectric conversion efficiency.

A conventional amorphous-silicon based thin film solar cell has a basic structure that comprises a transparent substrate, a transparent conductive layer, a semiconductor layer constituted by a PIN structure, and an electrode layer. An incident light passing through one side of the transparent substrate will cause generation of electron-hole pairs in the semiconductor layer so as to form photocurrent. The PIN structure is regarded as an intrinsic layer constituted by applying hydrogenated amorphous silicon (a-Si:H) and then inducing extra middle energy band by doping atoms so as to overlap the energy bands of conduction band and valence band. So far, the conversion efficiency of the thin solar cells can be increased based on choosing microcrysatline silicon(mc-Si:H) as an intrinsic layer for subsequently doping while stacking mc-Si:H with amorphous silicon material.

As for film solar cells, the quality of the photoelectric conversion efficiency is mainly dominated by the photo-absorption rate of the semiconductor layer because the photo-absorption rate is a key factor to determine a voltage and current output for the solar cells. Incident light may directly pass into film solar cells, or be scattered by other objects on the earth's surface and then be diffused. There is about 80 percent of the incident light directly passing into the film solar cells, however such direct incident light has a shorter light path and cannot be absorbed efficiently. Therefore, the shorter light path may diminish absorption efficiency of the semiconductor layer in the thin film solar cells, and can increase loss of the unabsorbed light beam. Besides, the PIN structure constituted either by the hydrogenated amorphous silicon or microcrystalline silicon (mc-Si) causes the limit to increase the photoelectric conversion efficiency. The mental electrode layer in the thin film solar cells can cause such effect of light reflection, and can partially reflect the unabsorbed light beam to the semiconductor layer so that the semiconductor layer can reabsorb the unabsorbed light beam. However, it is little help to increase the photoelectric conversion efficiency.

In order to resolve the aforementioned of photoelectric conversion inefficiency, the prior arts have disclosed such stacking mechanisms of multiple PIN structures, for example, hydrogenated amorphous-silicon and micro-silicon being chosen for forming thin film solar cells so as to enhance the photo-absorption efficiency and photoelectric conversion efficiency. However, the stacking structure will diminish light transparency so as to further diminish the photo-absorption and photoelectric conversion efficiency. On the other hand, other prior arts have disclosed an approach to increasing surface texture or roughing the surface of an incident side of the transparent substrate for the purpose of light scattering to ensure that the light can enter the thin film solar cells from more different angels in order to increase the light paths of passing through the semiconductor layer. Therefore, an interlayer (e.g. reflection layer) is provided between the amorphous-silicon semiconductor layer and the microcrystalline-silicon semiconductor layer, and is made of a transparent conducting oxide (TCO) such that the interlayer layer can somehow overcome the aforementioned of photoelectric conversion inefficiency. However, the conventional solar cells provided with an interlayer, for example, 600 Å-thick or 800 Å-thick interlayer, has to deal with another problem of decreased quantum efficiency QE (unit in percentage) particularly at the wave lengths in a range of about 500 nm to 1100 nm, compared to another conventional solar cells without the interlayer.

Therefore, the aforementioned prior arts still have limitations to increase photoelectric conversion efficiency, and the result is still not significant. Therefore, a need exists for providing thin film solar cells with high absorption efficiency particularly in the semiconductor layer.

### SUMMARY OF THE INVENTION

In light of the aforesaid problems, a thin film solar cell has been disclosed in the invention. The thin film solar cell comprises multiple layers provided with materials having total internal reflection effect and/or reflection effect so that the photoelectric conversion effect is improved.

In order to overcome the aforementioned shortcomings, the present invention provides a thin film solar cell that comprises a substrate, a transparent conductive layer, a first semiconductor layer, a reflection layer, a reflection enhancing layer, a second semiconductor layer and an electrode layer. The transparent conductive layer is formed on the substrate, and the first semiconductor layer is formed on the transparent conductive layer. The reflection layer is made of an opaque conductive material and formed on the first semiconductor layer, and the reflection layer has such a discontinuous surface that consists of a plurality of light-transmissive parts formed by removing part of the reflection layer, and a plurality of remaining parts surrounding the light-transmissive parts. The light-transmissive parts extended through the reflection layer guide part of the incident light to enter the second semiconductor layer, and the remaining parts of the reflection layer reflect part of the incident light to the first semiconductor layer. Moreover, the light-transmissive parts can have an area ratio equal to or larger than that of said remaining parts in the reflection layer. Therefore, part of the first semiconductor layer near the remaining parts of the reflection layer can obtain an increased short circuit current Jsc due to an advantage of light reflection of the remaining parts, so as to maintain the higher quantum efficiency in the solar cell of the present invention in comparison with the conventional interlayer of TCO material with the less light reflection. On the other hand, such particular design of the reflection layer can be provided to increase Jsc in a cost saving fashion without increasing the thickness of the first semiconductor layer when the quantum efficiency of the solar cell is desired to increase to some extent.

Besides, the reflection enhancing layer is formed on the reflection enhancing layer. The reflection enhancing layer has at least a stacking layer that comprises a low refraction index layer and a high refraction index layer. The low refraction index layer has a relatively low refraction index compared to the high refraction index layer. The second semiconductor layer is formed on the reflection enhancing layer. The electrode layer electrode layer is formed on the second semiconductor layer. Each of the first semiconductor layer and the second semiconductor layer is formed to have a junction structure such as single junction, double junctions, triple junctions, or more-than-three junctions. The high refraction index layer is formed on the low refraction index layer, and the plurality of light-transmissive parts are further extended to the reflection enhancing layer so as to reduce part of the incident light reflected from the reflection enhancing layer, and thereby improving the photo-absorption of the second semiconductor layer as well as avoiding the decreased quantum efficiency.

Besides, the transparent conducive layer, the low refraction index layer, and the high refraction index layer are formed of a transparent conducting oxide (TCO) film. The transparent conductive layer can be made of Tin dioxide (SnO₂), Indium tin oxide (ITO), Indium zinc oxide (IZO), Aluminum zinc oxide (AZO), Gallium zinc oxide (GZO), Zinc oxide (ZnO) and Silicon dioxide (SiO₂). The reflection layer is made of opaque conductive materials, such as mental, nonmetallic material (e.g. graphite), or combination thereof. The first semiconductor layer has an energy gap higher than that of the second semiconductor layer. The first semiconductor layer is constituted by a PIN structure that is made of amorphous silicon (a-Si). The second semiconductor layer is constituted by a PIN structure that is made of microcrystalline silicon (mc-Si). The substrate is made of such material selected from any kind of glass, quartz, and transparent plastics and flexible. The metal layer comprises at least a mental layer selected from aluminum (Al), nickel (Ni), gold (Au), silver (Ag), chromium (Cr), titanium (Ti) and palladium (Pd).

Besides, the reflection enhancing layer is provided to allow an incident light to enter into the low refraction index layer having a lower refraction index from the high refraction index layer having a higher refraction index, thereby generating the total internal reflection effect to allow the incident light further to re-enter the first semiconductor layer or the second semiconductor layer for the purpose of improving light reabsorption of the semiconductor layers. On the other hand, the opaque reflection layer can reflect the incident light to the first semiconductor layer so as to enhance the photo-absorption of the first semiconductor layer.

The aforementioned thin film solar cell has such reflection enhanced layer with different refraction index of the stacking layer to achieve the total internal reflection effect and photo-reflection effect on the reflection layer, and thereby guiding the unabsorbed light beam passed through the first and second semiconductor layers to re-enter into the two semiconductor layers so as to increase the light path within two semiconductor layers for improving reabsorption rate of the unabsorbed light beam and enhancing the photoelectric conversion efficiency. In the meanwhile, reduction of the light transmittance due to the stacking layer together with disadvantages of photo-absorption and photoelectric conversion efficiency due to the surface texture or roughing treatment of the transparent substrate can be improved for the conventional thin film solar cell, and thus the application and wide spread of the thin film solar cell will lead to success.

Although a preferred embodiment of the invention has been described for purposes of illustration, it is understood that various changes and modifications to the described embodiment can be carried out without departing from the scope and the spirit of the invention as disclosed in the appended claims.

### BRIEF DESCRIPTION OF DRAWINGS

The structure and the technical means adopted by the present invention to achieve the above and other objectives can be best understood by referring to the following detailed description of the preferred embodiments and the accompanying diagrams.

FIG. 1 is a sectional view that shows a thin film solar cell according to a first preferred embodiment of the invention.

FIG. 2 is a sectional view that shows another thin film solar cell according to a second preferred embodiment of the invention.

FIG. 3 is a schematic view that shows reflection and total reflection of an incident light in a thin film solar cell according to the first preferred embodiment of the invention.

FIG. 4 is a schematic view that shows reflection and total reflection of an incident light in a thin film solar cell according to the second preferred embodiment of the invention.

FIG. 5 is a schematic view to show different widths of light-transmissive parts extended through the reflection layer and reflection enhancing layer according to the first preferred embodiment of the present invention.

FIG. 6 is a fragmented view to show different Jsc values distributed at the first semiconductor layer and the second semiconductor layer according to the first preferred embodiment of the present invention.

### DETAILED DESCRIPTION OF PREFERRED EMBODIMENTS

A thin film solar cell thereof has been disclosed in the invention; wherein the principles of photoelectric conversion employed in solar cell may be easily comprehended by those of ordinary skill in relevant technical fields, and thus will not be further described hereafter. Meanwhile, it should be noted that the drawings referred to in the following paragraphs only serve the purpose of illustrating structures related to the characteristics of the disclosure, and are not necessarily drawn according to actual scales and sizes of the disclosed objects.

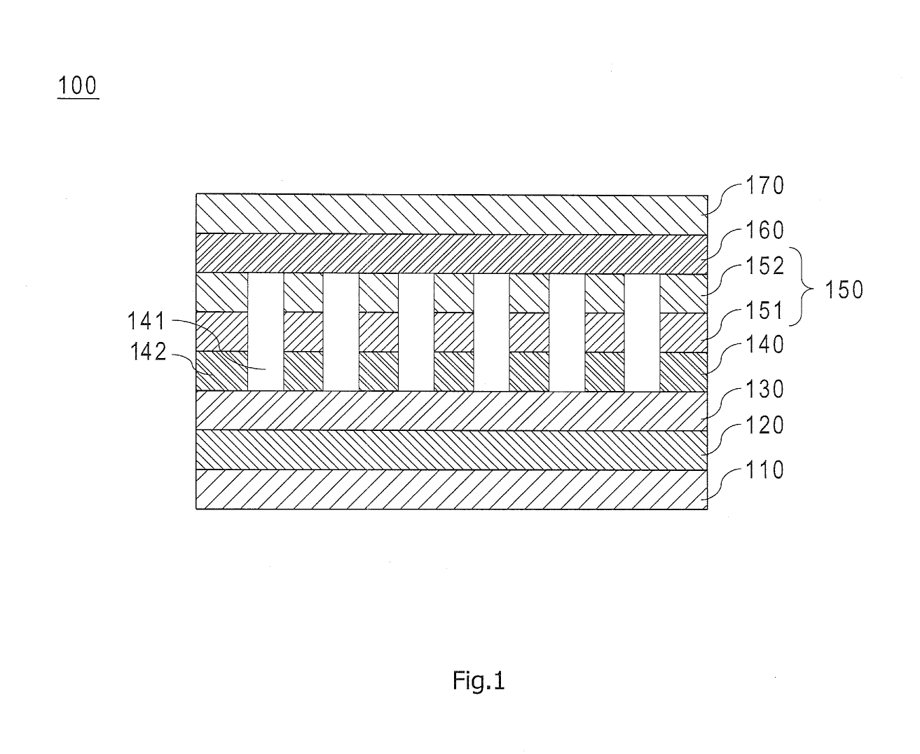

Refer to FIG. 1, which is a sectional view that shows a thin film solar cell according to the first preferred embodiment of the invention. The thin film solar cell 100 comprises a substrate 110, a transparent conductive layer 120, a first semiconductor layer 130, a reflection layer 140, a reflection enhancing layer 150, a second semiconductor layer 160, and an electrode layer 170. The reflection enhancing layer 150 can enable an incident light to generate a total internal reflection, and reflect the incident light into the second semiconductor layer 160 so as to enhance reabsorption efficiency of the second semiconductor layer 160. On the other hand, the reflection layer 140 can reflect the incident light into the first semiconductor layer 130, and thereby enhancing the photo-absorption efficiency of the first semiconductor layer 130. The reflection layer 140 and the reflection enhancing layer 150 are provided to improve the photoelectric conversion effect in the thin film solar cell 100. Besides, the reflection enhancing layer 150 formed on the reflection layer 140 has at least a stacking layer that includes a low refraction index layer 151 and a high refraction index layer 152. The low refraction index layer 151 has a refraction index (n) relatively lower than that of the high refraction index layer 152. The high refraction index layer 152 is formed on the low refraction index layer 151.

The substrate 110 has one surface as an incident side. A material used for the substrate 110 can be one of glass, quartz, transparent plastics and flexible substrate, and it should not be limited to the afore-mentioned materials. Any transparent material can be used here so as to allow the incident light to enter the inside of the thin film solar cell 100.

The transparent conductive layer 120 formed on another surface of the substrate 110 is a transparent conducting oxide (TCO) film, and has a high visual light transparency index and a low impedance value. The transparent conductive layer 120 can be one of Tin dioxide (SnO₂), Indium tin oxide (ITO), Indium zinc oxide (IZO), Aluminum zinc oxide (AZO), Gallium zinc oxide (GZO), Zinc oxide (ZnO) and Silicon dioxide (SiO₂), or combination thereof.

The first semiconductor layer 130 is formed on the transparent conductive layer 120 and has a junction structure such as single junction, double junctions, triple junctions, or more-than-three junctions. In the aforementioned preferred embodiment of the invention, the first semiconductor layer 130 has an energy gap higher than that of the second semiconductor layer 160. The first semiconductor layer 130 is constituted by a PIN structure made of amorphous silicon (a-Si) so as to generate photovoltaic effect and electron-hole pairs in order to provide photocurrent.

Particularly, the reflection layer 140 formed on the transparent conductive layer 120 is made of opaque conductive materials like mental, nonmetallic material (e.g. graphite), or combination thereof so that the reflection layer 140 has a characteristic of high refraction. After the incident light passes through the first semiconductor layer 130, the unabsorbed light will enter the reflection layer 140. The reflection layer 140 can reflect the residual unabsorbed light into the first semiconductor layer 130 such that the first semiconductor layer 130 will reabsorb the residual unabsorbed light. Since the reflection layer 140 is opaque, a plurality of light-transmissive parts 141 and remaining parts 142 surrounding the light-transmissive parts 141 can be provided in the reflection layer 140 where each of the light-transmissive parts 141 is formed by removing part of the reflection layer 140, so as to guide part of the incident light to enter the second semiconductor layer 160 through the reflection enhancing layer 150, and each of the remaining parts 142 can reflect part of the incident light to the first semiconductor layer 130. It is noted that the reflection layer 140 can also be formed with the light-transmissive parts 141 while using mask to form the reflection layer 140.

Besides, the plurality of light-transmissive parts 141 in the reflection layer 140 can be further extended through the low refraction index layer 151 and the high refraction index layer 152 of the reflection enhancing layer 150 by removing part of the low refraction index layer 151 and part of the high refraction index layer 152 of the reflection enhancing layer 150, so as to avoid part of the incident light being reflected from the reflection enhancing layer 150, and thereby improving the light absorption of the second semiconductor layer 160.

Each of the plurality of light-transmissive parts 141 has a configuration like a separation groove or through holes while producing the reflection layer 140 of the thin film solar cell. After the incident light passes through the second semiconductor layer 160, the residual unabsorbed light will be reflected from the electrode layer 170 to the reflection enhancing layer 150. One phenomenon that the incident light enters the low refraction index layer 151 from the high refraction index layer 152 is similar to another phenomenon that the light enters the lower refraction media from higher refraction media. Either phenomenon will cause a total internal reflection effect of light. The total internal reflection effect of light will enable the reflected light back to the second semiconductor layer 160 so that the second semiconductor layer 160 will reabsorb the reflected light.

The low refraction index layer 151 and the high refraction index layer 152 are made of a transparent conductor oxide film and selected from one of Tin dioxide (SnO₂), Indium tin oxide (ITO), Indium zinc oxide (IZO), Aluminum zinc oxide (AZO), Gallium zinc oxide (GZO), Zinc oxide (ZnO) and Silicon dioxide (SiO₂), or combination thereof. Each of the aforementioned materials has its own refraction index. The refraction index can be controlled by different manufacturing processes so as to fall within a desirable range. For example, other materials can be added so that the transparent conductor oxide film has two different refraction index. Therefore, two materials are selected according to the higher and lower desirable refraction index: one for relatively lower refraction index and another for relatively higher refraction index. The first material of relatively lower refraction index is used to produce the low refraction index layer 151 and the second material of relatively higher refraction index is used to produce the high refraction index layer 15 as well. Both the low refraction index layer 151 and the high refraction index layer 152 are mixed as a pair to form a stacking layer. Besides, the pair number required for the stacking layer of the reflection enhancing layer 150 can be adjusted based on the enhancement of photoelectric conversion efficiency in thin film solar cell 100.

The second semiconductor layer 160 formed on the reflection enhancing layer 150 has a junction structure such as single junction, double junctions, triple junctions, or more-than-three junctions. In the first preferred embodiment of the invention, the second semiconductor layer 160 has an energy gap smaller than that of the first semiconductor layer 130. The second semiconductor layer 160 is constituted by a PIN structure made of microcrystalline silicon (mc-Si) or microcrystalline silicon germanium (mc-SiGe) so as to generate photovoltaic effect and electron-hole pairs to form photocurrent.

The electrode layer 170 formed on the second semiconductor layer 160 comprises at least a metal layer having a material of aluminum (Al), nickel (Ni), gold (Au), silver (Ag), chromium (Cr), titanium(Ti) or palladium(Pd). Since the electrode layer 170 is made of metal so that the unabsorbed incident light will be reflected from the electrode layer 170 to the second semiconductor layer 160 and reflection enhancing layer 150 again when passing through the second semiconductor layer 160 because of material characteristic of the electrode layer 170.

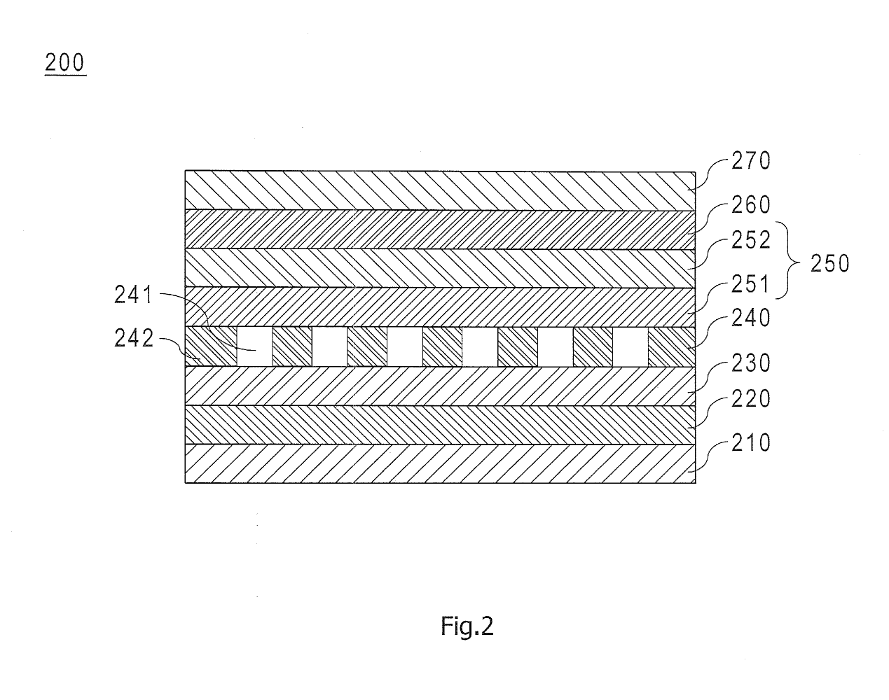

Refer to FIG. 2, which is a sectional view that shows a thin film solar cell according to the second preferred embodiment of the invention. The structure of the thin film solar cell 200 is similar to that of the thin film solar cell 100 except that the light-transmissive parts 141 are extended through the reflection layer 140 and the reflection enhancing layer 150 in the first preferred embodiment, and the light-transmissive parts 241 are extended through the reflection layer 240 in the second preferred embodiment. In addition, materials and functions disclosed in each layer of the thin film solar cell 200 are also similar to that of the thin film solar cell 100. The thin film solar cell 200 comprises a substrate 210, a transparent conductive layer 220, a first semiconductor layer 230, a reflection layer 240, a reflection enhancing layer 250, a second semiconductor layer 260, and an electrode layer 270. The reflection enhancing layer 250 can enable an incident light to generate a total internal reflection, and reflect the incident light into the first semiconductor layer 230 so as to enhance reabsorption efficiency of the first semiconductor layer 230. Since the reflection layer 240 is opaque, a plurality of light-transmissive parts 241 and remaining parts 242 surrounding the light-transmissive parts 241 can be further provided in the reflection layer 240 where each of the light-transmissive parts 241 is formed by removing part of the reflection layer 240 so as to guide part of the incident light to enter the second semiconductor layer 260, and each of the remaining parts 242 can reflect part of the incident light to the first semiconductor layer 230.

The reflection enhancing layer 250 has at least a stacking layer that includes a low refraction index layer 251 and a high refraction index layer 252. The low refraction index layer 251 has a refraction index (n) relatively lower than that of the high refraction index layer 252. The low refraction index layer 251 is formed on the high refraction index layer 252. When the incident light passes through the first semiconductor layer 230, the residual unabsorbed light will be reflected to the first semiconductor layer 230 again resulting from the total internal reflection effect because the incident light enters the low refraction index layer 251 from the high refraction index layer 252, that is, light entering the lower refraction media from higher refraction media. Therefore, the reflected light will enter the first semiconductor layer 230 again for reabsorption.

Each layer formed in the aforementioned thin film solar cell 100 or the thin film solar cell 200 is stacked in such sequence by the conventional methods including sputtering, atmosphere thermal chemical vapor deposition, low pressure chemical vapor deposition (LPCVD), electron cyclotron resonance chemical vapor deposition (ECR-CVD), D.C glow discharge, radio frequency glow discharge, hot filament chemical vapor deposition, and it should not be limited to the afore-mentioned methods.

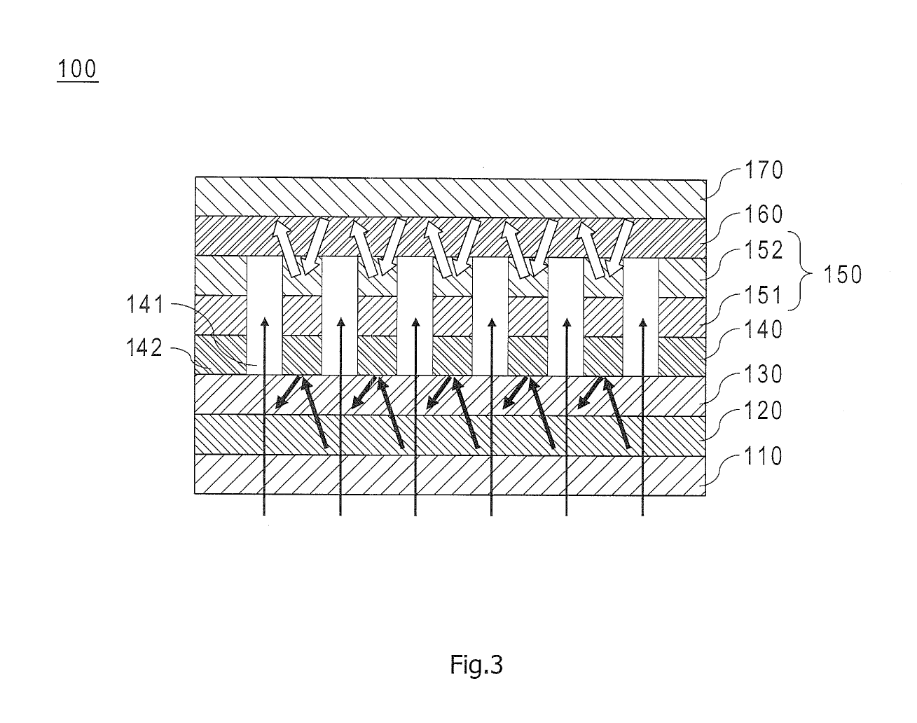

Refer to FIG. 3, which is a schematic view that shows reflection and total internal reflection of the incident light entering the thin film solar cell according to the first preferred embodiment of the invention. When the incident light enters the thin film solar cell 100, the incident light passes through the substrate 110, the transparent conductive layer 120 and the first semiconductor 130 in such a sequence, and then enters the reflection layer 140. In this moment, the opaque reflection layer 140 can reflect the incident light back to the first semiconductor 130 (indicated by a bold solid black arrow line representative of the light reflected path in FIG. 3). On the hand, the plurality of light-transmissive parts 141 are provided through the reflection layer 140 and the reflection enhancing layer 150 so that the incident light can pass through the plurality of light-transmissive parts 141 of the reflection enhancing layer 150, and then enter the second semiconductor layer 160. Since the plurality of light-transmissive parts 141 can be extended through the reflection enhancing layer 150 so that the incident light can directly enter the second semiconductor layer 160 by means of the plurality of light-transmissive parts 141 for preventing part of the incident light from being reflected from the reflection enhancing layer 150. Also, the plurality of remaining parts 142 can reflect part of the incident light to the semiconductor layer 130 (indicated by bold solid black arrow line representative of the light reflected path in FIG. 3) so that the first semiconductor 130 reabsorbs the part of the incident light. Finally, the incident light arrives at the mental electrode layer 170, and then the mental electrode layer 170 reflects the incident light back to the reflection enhancing layer 150. Subsequently, the incident light enters to the low refraction index layer 151 from the high refraction index layer 152 so as to generate the total internal reflection effect of light (indicated by solid white arrow line representative of the light reflected path in FIG. 3). The total internal reflection effect of light will enable the reflected light back to the second semiconductor layer 160 so that the second semiconductor layer 160 will reabsorb the reflected light.

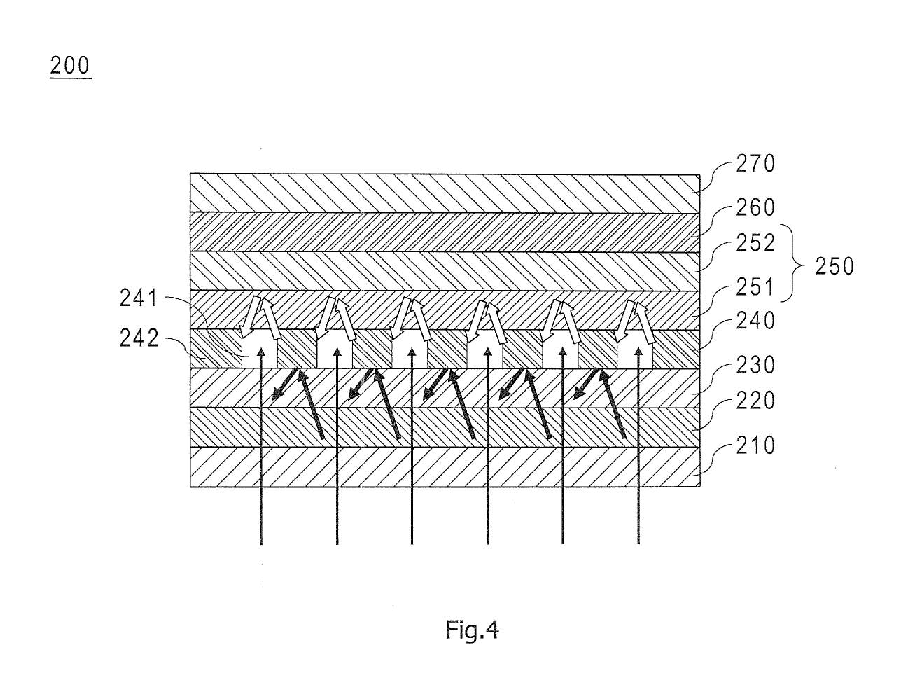

Refer to FIG. 4, which is a schematic view that shows reflection and total internal reflection of the incident light entering the thin film solar cell according to the second preferred embodiment of the invention. When the incident light enters into thin film solar cell 200, the incident light passes through the substrate 210, the transparent conductive layer 220, the first semiconductor 230 in such a sequence, and then enters the reflection layer 240. In this moment, the opaque reflection layer 240 can reflect part of the incident light back to the first semiconductor 230 by means of the plurality of remaining parts 242 (indicated by a bold solid black arrow line representative of the light reflected path in FIG. 4) so that the first semiconductor 230 reabsorbs the reflected incident light. On the hand, a plurality of light-transmissive parts 241 are provided through the reflection layer 240 so that the incident light can directly enter the low refraction index layer 251 of the reflection enhancing layer 250 through the plurality of light-transmissive parts 241 (indicated by solid white arrow line representative of the total internal reflection path in FIG. 4) so as to generate the total internal reflection effect of light. Therefore, the total internal reflection effect of light will enable the reflected light back to the first semiconductor layer 230 so that the first semiconductor layer 230 will reabsorb the reflected light.

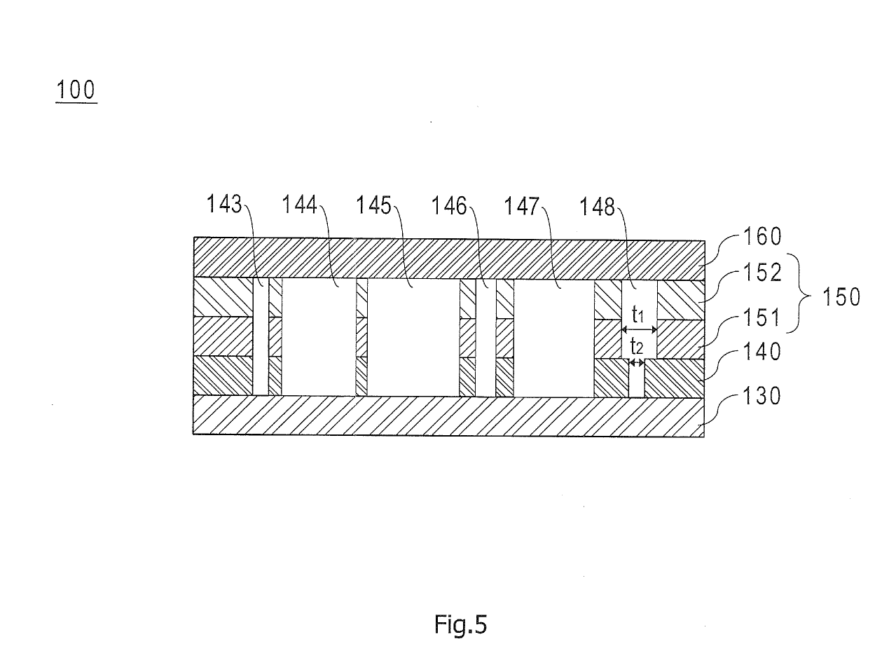

Referred to FIG. 5, it shows each different width for each light-transmissive part 143,144,145,146,147,148 as being extended through the reflection layer 140 and reflection enhancing layer 150 according to the first preferred embodiment of the present invention. It is noted that the light-transmissive part 148 has the width t2 in the reflection layer 140 narrower than width t1 of the light-transmissive part 148 in the reflection enhancing layer 150. Besides, whether the width of each light-transmissive part is larger or smaller than the width of each remaining part surrounding the light-transmissive part depends on the actual situation, for example, the light-transmissive part 143,144,145,146,147. On the other hand, each light-transmissive part having the different width can be also applicable to the second embodiment of the present invention.

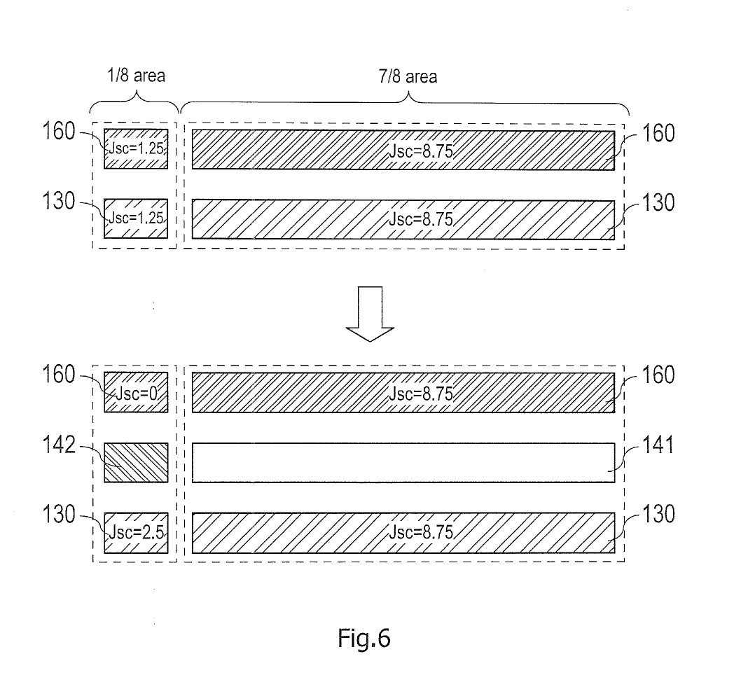

Referred to FIG. 6, it is shown that the light-transmissive part 141 has an area ratio equal to or larger than the area ratio of the remaining part 142 in the reflection layer 140. For, example, the light-transmissive part 141 occupies ⅞ area compared to the ⅛ area of the remaining part 142 in the reflection layer 140. On the other hand, the first semiconductor layer 130 (in ⅛ area) near the remaining part 142 of the reflection layer 140 (on the lower part of FIG. 6) will produce 2.5 mA/cm² of Jsc increased by 1.25 mA/cm² from 1.25 mA/cm² in the first semiconductor layer 130 (in ⅛ area) without inserting the reflection layer 140 (on the upper part of FIG. 6). Therefore, part of the first semiconductor layer 130 near the remaining parts 142 of the reflection layer can obtain an increased short circuit current Jsc due to an advantage of the incident light reflection from the remaining parts 142, so as to maintain the higher quantum efficiency in the solar cell of the present invention. Moreover, such particular design of the reflection layer 140 can be provided to increase Jsc in a cost saving fashion without increasing the thickness of the first semiconductor layer 130 when the quantum efficiency of the solar cell is desired to increase to some extent. Also, the same principle of the particular design of the reflection layer can be applicable to the second preferred embodiment of the present invention.

Besides, the reflection enhancing layer 150,250 can be stacked as one or multiple layers (e.g. multiple reflection enhancing layers) to control the photo reflectance through the solar cell for different range of wavelengths of the incident light. For example, eight stacks of the reflection enhancing layer can produce the optimum reflectance (100% total reflection) for a wavelength range of about 400 nm to 600 nm; or one stack of the reflection enhancing layer can produce the optimum reflection for a wavelength range of about 800 nm to 1000 nm How many stacking layers required for the solar cell is determined on the actual situation or its application.

In summary, the reflection enhancing layers 150 and 250 are provided to enable the incident light to generate the total internal reflection effect of light, and to guide the incident light further into the first semiconductor layers 130,230 or into the second semiconductor layers 160 and 260 such that enhancement of absorption efficiency in the first semiconductor layers 130 and 230 can be achieved. On the other hand, the opaque reflection layers 140,240 can reflect the incident light to the first semiconductor 130, 230 such that enhancement of absorption efficiency in the first semiconductor layers 130, 230 can be achieved, and photoelectric conversion effect of the thin film solar cells 100, 200 can be further achieved as well.

Although a preferred embodiment of the invention has been described for purposes of illustration, it is understood that various changes and modifications to the described embodiment can be carried out without departing from the scope and the spirit of the invention as disclosed in the appended claims.

What is claimed is:

1. A thin film solar cell, comprising:
a substrate provided to allow an incident light to pass therethrough;
a transparent conductive layer formed on said substrate;
a first semiconductor layer formed on said transparent conductive layer;
a reflection layer formed on said first semiconductor layer, said reflection layer being highly refractive and having a discontinuous surface consisting of a plurality of light-transmissive parts formed, and a plurality of remaining parts surrounding said light-transmissive parts in said reflection layer;
a reflection enhancing layer formed on said reflection layer, said reflection enhancing layer having at least a stacking layer that includes a low refraction index layer and a high refraction index layer;
a second semiconductor layer formed on said reflection enhancing layer; and
an electrode layer formed on said second semiconductor layer; wherein said light-transmissive parts through said reflection layer guide part of said incident light to enter said second semiconductor layer, and said remaining parts in said reflection layer reflect part of said incident light to said first semiconductor layer; and wherein said reflection enhancing layer receives part of said incident light reflected from said electrode layer and then reflects it to enter said second semiconductor layer.

2. The thin film solar cell of claim 1, wherein said light-transmissive parts has an area ratio equal to or larger than that of said remaining parts in said reflection layer.

3. The thin film solar cell of claim 1, wherein each said light-transmissive parts in said reflection layer is further extended to said reflection enhancing layer.

4. The thin film solar cell of claim 3, wherein said light-transmissive parts has an area ratio equal to or larger than that of said remaining parts in said reflection enhancing layer.

5. The thin film solar cell of claim 1, wherein said high refraction index layer is formed on said low refraction index layer.

6. The thin film solar cell of claim 1, wherein said low refraction index layer is formed on said high refraction index layer.

7. The thin film solar cell of claim 1, wherein said high refraction index layer, said low refraction index layer and said transparent conductive layer are formed of a transparent conducting oxide (TCO).

8. The thin film solar cell of claim 7, wherein said transparent conducting oxide (TCO) is selected from the group consisting of SnO2, ITO, IZO, AZO, GZO, ZnO and SiO2.

9. The thin film solar cell of claim 1, wherein said reflection layer is made of an opaque conductive material.

10. The thin film solar cell of claim 9, wherein said reflection layer is made of metal, non-metal, or combination thereof.

11. The thin film solar cell of claim 10, wherein said reflection layer is made of graphite.

12. The thin film solar cell of claim 1, wherein said first semiconductor layer has a junction structure formed of single junction, double junctions, triple junctions, or more-than-three junctions.

13. The thin film solar cell of claim 1, wherein said second semiconductor layer has a junction structure formed of single junction, double junctions, triple junctions, or more-than-three junctions.

14. The thin film solar cell of claim 3, wherein each said light-transmissive part has a width in said reflection layer narrower than that of each said light-transmissive part in said reflection enhancing layer.

15. The thin film solar cell of claim 1, wherein said first semiconductor layer has an energy gap higher than that of said second semiconductor layer.

16. The thin film solar cell of claim 15, wherein said first semiconductor layer is constituted by a PIN structure made of amorphous silicon (a-Si).

17. The thin film solar cell of claim 15, wherein said second semiconductor layer is constituted by a PIN structure made of microcrystalline silicon (mc-Si) or microcrystalline silicon germanium (mc-SiGe)

18. The thin film solar cell of claim 1, wherein said substrate is selected from the group consisting of glass, quartz, transparent plastics and flexible substrate.

19. The thin film solar cell of claim 1, wherein said electrode layer comprises a metal layer.

20. The thin film solar cell of claim 19, wherein said metal layer is selected from the group consisting of aluminum (Al), nickel(Ni), gold(Au), silver(Ag), chromium(Cr), titanium(Ti) and palladium(Pd).
